(19) United States
(12) Patent Application Publication
(10) Pub. No.: US 2005/0273286 A1
(43) Pub. Date: Dec. 8, 2005

(54) Methods for identifying brain nuclei from micro-electrode signals

(75) Inventors: Benoit M. Dawant, Nashville, TN (US); J. Michael Fitzpatrick, Nashville, TN (US); Ebru Cetinkaya, Nashville, TN (US); Pierre-Francois Dominique D'Haese, Nashville, TN (US)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: Vanderbilt University, Nashville, TN (US)

(21) Appl. No.: 11/134,036

(22) Filed: May 20, 2005

Related U.S. Application Data
(60) Provisional application No. 60/573,168, filed on May 21, 2004.

(51) Int. Cl. G01R 29/26

(52) U.S. Cl. 702/73

(57) ABSTRACT

A method for classifying microelectrode recording signals. In one embodiment, the method includes the steps of performing wavelet transforms on each of the microelectrode recording signals to compute corresponding wavelet coefficients, respectively, extracting features from the computed wavelet coefficients for each of the microelectrode recording signals, respectively, and classifying the extracted features so as to classify the microelectrode recording signals.

### CROSS-REFERENCE TO RELATED PATENT APPLICATION

This application claims the benefit, pursuant to 35 U.S.C. §119(e), of provisional U.S. patent application Ser. No. 60/573,168, filed on May 21, 2004, entitled “Method for Identifying Brain Nuclei from Micro-Electrode Signals,” by Benoit M. Dawant, J. Michael Fitzpatrick, Ebru Cetinkaya, and Pierre-Francois Dominique D'Haese, which is incorporated herein by reference in its entirety.

Some references, which may include patents, patent applications and various publications, are cited and discussed in the description of this invention. The citation and/or discussion of such references is provided merely to clarify the description of the present invention and is not an admission that any such reference is “prior art” to the invention described herein. All references cited and discussed in this specification are incorporated herein by reference in their entireties and to the same extent as if each reference was individually incorporated by reference. In terms of notation, hereinafter, “[n]” represents the nth reference cited in the reference list. For example, [6] represents the 6th reference cited in the reference list, namely, J. H. Falkenberg, J. McNames, M. Aboy, K. J. Burchiel, “Segmentation of Extracellular Microelectrode Recordings with Equal Power,” Ann. Int. Conf. of the IEEE Eng. in Medicine and Biology—Proceedings, Cancun, Mexico, pp. 2475-2478, 2003.

### FIELD OF THE INVENTION

The present invention generally relates to identifying microelectrode recording signals, and in particular to the utilization of wavelet decompositions to classify and visualize microelectrode recording signals so as to identify neuronal structures associated with the microelectrode recording signals.

### BACKGROUND OF THE INVENTION

Since its first Food and Drug Administration approval in 1998, deep-brain stimulation (hereinafter “DBS”) has gained significant popularity in the treatment of a variety of brain-controlled disorders, including movement disorders [1, 2]. The therapy of the DBS has significant applications in the treatment of tremor, rigidity, and drug induced side effects in patients with Parkinson's disease (hereinafter “PD”) and essential tremor. Generally, such treatment involves placement of a DBS microelectrode probe through a burr hole drilled in the patient's skull, followed by placement of the microelectrode probe and then applying appropriate stimulation signals through the microelectrode probe to the physiological target. Effective stimulation occurs only when the microelectrode probe is placed in the physiological target [2]. Thus, finding a physiological target and then permanently placing the microelectrode probe so that it efficiently stimulates such target is very important.

Yet finding an optimal physiological target in deep brain stimulation implants for the treatment of movement disorders is a particularly complicated task. This is especially true for the treatment of symptoms that cannot be tested at the operating table during the microelectrode probe implantation. For instance, it is practically impossible to test walking and postural stability in PD patients during the DBS probe implantation. Two other major PD symptoms, Rigidity and Akinesia, are also considered difficult to evaluate quantitatively during DBS probe implantation. On the other hand, the surgical targets of interest involve deep brain nuclei or subregions within the subthalarnic nucleus (hereinafter “STN”) or globus pallidus intemus (hereinafter “Gpi”). These structures are not visible in any current imaging modalities, such as magnetic resonance image (hereinafter “MRI”), X-ray computed tomography (hereinafter “CT”), or positron emission tomography (hereinafter “PET”). In normal clinical practices, these targets are chosen pre-operatively based on anatomical landmarks identified on images of MRI, CT or PET. But many factors can influence the accuracy of the anatomic target, e.g., geometric distortions in MRI, imperfect visualization of target structures, or possible brain shift that may occur after opening the skull [3, 4]. Therefore, information acquired intra-operatively both from microelectrode recordings (hereinafter “MER”) and micro-stimulation, among other things, is important for optimizing DBS position.

As a microelectrode probe is placed in a surgical target of a brain of a patient, a MER signal is acquired by the microelectrode probe and translated into an audio signal as well as a visual presentation, which enable neurosurgeons to hear and visualize neuronal activities in different areas of the brain. By visually analyzing the time domain behavior of the MER signals, neurosurgeons may establish the fuictional borders of the neuronal structures. So far, several types of analysis of the MER signals have been reported. A spike train analysis of the MER signals involves in detection of the spikes of the MER signals and computation and display of various features extracted from the spike train, e.g. the histogram of the inter-spike intervals as well as various indices computed from the histograms, such as burst index, pause index, and pause ratio. Because the transition between neuronal structures is associated with a change in the firing patterns, a natural way to attempt to discriminate between these structures is to use features extracted from the spike train. Usually, neuronal structures can be classified by three parameters: (1) kinesthetic activity (response to movement), (2) phasic activity (spike pattern), and (3) tonic activity (firing rate). The phasic activity can be analyzed based on subjective descriptions of the firing patterns and binary plots of spike activity [5]. The analysis of tonic and kinesthetic activity can be done based on objective characteristics of the spike train, e.g. firing rate or indices computed from inter-spike interval histograms. Neurosurgeons examine the spike activity in the MER signal to confirm the final placement of the microelectrode probe while passing the microelectrode probe through the brain. However, the analysis requires neurosurgeons several years of experience and depends largely on human observation and observer interpretation of the spike activity, which may introduce an element of human error and inconsistency.

In addition to the spike train analysis, power spectrum density (hereinafter “PSD”) method has also been used to classify the MER signals. The power spectrum-based method does not require spike detection. Instead, the Welch's power spectrum density of the MER signals and the average power are computed. The Welch's PSD method includes three main steps. At first, a time domain signals are divided into segments, possibly overlapping. Second, a modified periodogram of each segment is computed. And then the PSD estimates are averaged. The modified periodogram windows the time-domain signals prior to computing the fast Fourier transform (hereinafter “FFT”) in order to smooth the edges of the signal. Once a PSD estimate of the signal is computed, the average power is also computed as a new feature. It is obtained by summing the PSD values computed from a signal and by dividing the sum by the length of the PSD estimate. It is well known that the Fourier transform reveals frequency domain information of a signal, which indicates how much of a frequency component exists in the signal, but the information about when in time this frequency component exists is lost. This information is not important and required when the signal is stationary. It has been known that the complexity of brain activity results in non-stationary MER recordings [6]. For non-stationary signal whose frequency content constantly changes over time, the lost information maybe crucial for identifying the neuronal structures of a brain.

As an alternative, modern surgical workstations provide some tools for MER analysis. But most of these are cumbersome, their output difficult to interpret, they need manual tuning, and they require the neurosurgeons to mentally keep track of how the recordings change as the microelectrode moves through different brain structures [6].

Therefore, a heretofore unaddressed need exists in the art to address the aforementioned deficiencies and inadequacies.

### SUMMARY OF THE INVENTION

In one aspect, the present invention relates to a method for classifying MER signals. Each of the MER signals is acquired from a targeted region of a brain of a living subject and is related to a neuronal structure in the targeted region of the brain of the living subject. In one embodiment, each of the MER signals includes a time domain signal.

In one embodiment, the method includes the steps of performing wavelet transforms on each of the MER signals to compute corresponding wavelet coefficients, respectively, extracting features from the computed wavelet coefficients for each of the MER signals, respectively, and classifying the extracted features so as to classify the MER signals. The method further includes the step of forming a vector of the extracted features for each of the MER signals, where the vector of the extracted features corresponds to a pattern. Moreover, the method includes the step of creating a neural network having an input layer, an output layer and at least one hidden layer formed therebetween the input layer and the output layer, where the input layer has at least one neuron adapted for inputting patterns, and the output layer has at least one neuron adapted for outputting patterns corresponding to the input patterns, respectively. In one embodiment, the neural network is created with a multi-layer perceptron (hereinafter “MLP”) model.

In one embodiment, the performing step includes the step of decomposing each of the MER signals into N levels of signals and is performed with a mother wavelet function, where N is an integer greater than zero, and the mother wavelet function includes a Daubechies-5 mother wavelet function. The decomposing step, in one embodiment, has the steps of (a) filtering a MER signal into an approximation signal and a detail signal with a low-pass filter and a high-pass filter, respectively, where a low-pass filter and a high-pass filter are complementary to each other in frequency, (b) downsampling the approximation signal and the detail signal to produce an approximation coefficient and a detail coefficient, respectively, where both the approximation coefficient and the detail coefficient constitute one level of decomposition of the MER signal, and (c) repeating steps (a) and (b) on the downsampled approximation signal N-1 times so as to decompose the MER signal into N levels of signals such that a first level, a second level, . . . , and a Nth level of signals comprise cA₀=cA₁+cD₁, cA₁=cA₂+cD₂, . . . , and cA_{N-1}=cA_{N}+cD_{N}, respectively, where cA₀ corresponds to the MER signal, cA₁, cA₂, . . . , and cA_{N} are approximation coefficients of the first level, the second level, . . . , and the Nth level of signals, respectively, and cD₁, cD₂, . . . , and cD_{N} are detail coefficients of the first level, the second level, . . . , and the Nth of signals, respectively. In one embodiment, the downsampling step is performed with dyadic decimation such that each of an approximation coefficient cAⱼ and an detail coefficient cDⱼ at a jth level has an half number of samples of a j-1)th level of signals, where j=1, 2, . . . , N.

The extracted feature, in one embodiment, includes information of a frequency distribution of each of the MER signals, and information of an amount of changes of the frequency distribution of each of the MER signals. In one embodiment, the information of the frequency distribution comprises absolute mean values of the detail coefficients at each of N levels of signals, and the information of the amount of changes of the frequency distribution comprises standard deviations of the detail coefficients at each of N levels of signals.

In one embodiment, the classifying step has the steps of grouping vectors of the extracted features into a set of training data and a set of testing data, respectively, training the neural network with the set of training data so as to associate an output pattern with a corresponding input pattern, and testing the neural network with the set of testing data so as to identify an input pattern and to output an associated output pattern. The classifying step, in one embodiment, is performed with a Levenberg-Marquardt (hereinafter “LM”) back-propagation (hereinafter “BP”) algorithm.

Additionally, the method includes the step of de-noising each of the MER signals, respectively. In one embodiment, the de-noising step comprises the steps of decomposing a MER signal into multiple levels of signals, where each level of signals comprises an approximation coefficient and a detail coefficient, thresholding the detail coefficient of each level of signals with a corresponding threshold to produce a modified detail coefficient of the corresponding level of signals, and reconstructing the MER signal from approximation coefficients and modified detail coefficients of each level of signals.

In another aspect, the present invention relates to an apparatus for classifying MER signals. In one embodiment, the apparatus has a controller that is adapted for performing the steps of performing a wavelet transform on each of the MER signals to compute corresponding wavelet coefficients, respectively, extracting features from the computed wavelet coefficients for each of the MER signals, respectively, and classifying the extracted features so as to classify the MER signals. The controller in one embodiment includes a computer.

Furthermore, the apparatus has means for acquiring the MER signals. The acquiring means is in communication with the controller. In one embodiment, the acquiring means includes at least one microelectrode recording probe placed in a target region of a brain of a living subject. Moreover, the apparatus has a neural network communicating with the controller and having an input layer, an output layer and at least one hidden layer formed therebetween the input layer and the output layer, where the input layer has at least one neuron adapted for inputting patterns, and the output layer has at least one neuron adapted for outputting patterns corresponding to the input patterns. In one embodiment the neural network is created with a MLP model.

In yet another aspect, the present invention relates to software stored on a computer readable medium for causing a computing system to perform functions of performing wavelet transforms on each of MER signals acquired from a targeted region of a brain of a living subject to compute corresponding wavelet coefficients, respectively, extracting features from the computed wavelet coefficients for each of the MER signals, respectively, and classifying the extracted features so as to classify the MER signals.

In a further aspect, the present invention relates to a method for identifying a neuronal structure of a targeted region of a brain of a living subject from a MER signal that has at least one frequency band. In one embodiment, the method has the step of decomposing the MER signal into N levels of signals with a wavelet transformation. Each level of signals corresponds to a frequency band of the MER signal, and N is an integer greater than zero. The method further has the step of choosing a level of signals which is in the highest frequency band of the MER signal. The chosen level of signals comprises a Nth level of signals. In one embodiment, N equals to 5. Moreover, the method has the step of reconstructing the MER signal from the chosen level of signals. In one embodiment, the reconstructing step is performed with an inverse of the wavelet transformation. Furthermore, the method has the steps of thresholding the reconstructed MER signal and determining a neuronal structure of the targeted region of the brain of the living subject from the thresholded MER signal. Additionally, the method has the step of visualizing the thresholded MER signal.

In yet a further aspect, the present invention relates to an apparatus for identifying a neuronal structure of a targeted region of a brain of a living subject from a MER signal that has at least one frequency band. The MER signal is related to a neuronal structure in the targeted region of the brain of the living subject. In one embodiment, the apparatus includes a controller adapted for performing the steps of decomposing the MER signal into N levels of signals with a wavelet transformation, each level of signals corresponding to a frequency band of the MER signal, and N being an integer greater than zero, choosing a level of signals which is in the highest frequency band of the MER signal, reconstructing the MER signal from the chosen level of signals, thresholding the reconstructed MER signal, and determining a neuronal structure of the targeted region of the brain of the living subject from the thresholded MER signal.

The apparatus further includes means for acquiring the MER signal from the targeted region of the brain of the living subject for a predetermined period of time. The acquiring means is in communication with the controller. In one embodiment, the acquiring means has at least one microelectrode recording probe placed in the targeted region of the brain of the living subject, where the at least one microelectrode recording probe comprises at least one channel. Moreover, the apparatus has at least one display in communication with the controller for visualizing the thresholded MER signal.

In one aspect, the present invention relates to software stored on a computer readable medium for causing a computing system to perform functions of decomposing a MER signal acquired from a targeted region of a brain of a living subject into N levels of signals with a wavelet transformation, each level of signals corresponding to a frequency band of the MER signal, and N being an integer greater than zero, choosing a level of signals which is in the highest frequency band of the MER signal, reconstructing the MER signal from the chosen level of signals, thresholding the reconstructed MER signal, and determining a neuronal structure of the targeted region of the brain of the living subject from the thresholded MER signal.

In another aspect, the present invention relates to a method for feature extraction of at least one non-stationary signal. In one embodiment, the at least one non-stationary signal includes a MER signal acquired from a targeted region of a brain of a living subject that is related to a neuronal structure in the targeted region of the brain of the living subject. In one embodiment, the method has the steps of performing a wavelet transform on the at least one non-stationary signal to compute corresponding wavelet coefficients and extracting features from the computed coefficients. The performing step includes the step of discriminating between the at least one non-stationary signal with different frequency features. In one embodiment, the performing step includes the steps of decomposing the at least one non-stationary signal into N levels of signals, where each level of signals has an approximation coefficient and a detail coefficient and corresponding to a frequency band of the at least one non-stationary signal, and N is an integer greater than zero.

Furthermore, the method includes the step of choosing a level of signals which is in the highest frequency band of the at least one non-stationary signal, reconstructing the at least one non-stationary signal from the chosen level of signals, thresholding the reconstructed signal, and visualizing the thresholded signal. Additionally, the method includes the step of classifying the extracted features. In one embodiment, the classifying step is performed within a neural network and a Levenberg-Marquardt back-propagation algorithm, where the neural network is created with a multi-layer perceptron model.

In yet another aspect, the present invention relates to software stored on a computer readable medium for causing a computing system to perform functions of performing a wavelet transform on at least one non-stationary signal acquired from a targeted region of a brain of a living subject to compute corresponding wavelet coefficients and extracting features from the computed coefficients.

These and other aspects of the present invention will become apparent from the following description of the preferred embodiment taken in conjunction with the following drawings, although variations and modifications therein may be affected without departing from the spirit and scope of the novel concepts of the disclosure.

### BRIEF DESCRIPTION OF THE DRAWINGS

FIG. 1 shows a raw MER signal and a corresponding de-noised MER signal according to one embodiment of the present invention, (A) the raw MER signal, (B) the de-noised MER signal, (C) a zoomed view of the raw MER signal, and (D) a zoomed view of the de-noised MER signal.

FIG. 2 shows a flowchart of decomposing a MER signal into one level of signals according to one embodiment of the present invention.

FIG. 3 shows a flowchart of decomposing a MER signal into four levels of signals according to one embodiment of the present invention.

FIG. 4 shows architecture of a neural network created with a multi-layer perceptron model.

FIG. 5 shows a scheme of processing MER signal for identifying neuronal structure according to one embodiment of the present invention.

FIG. 6 shows a flowchart of pattern classification of MER signals with a neural network according to one embodiment of the present invention.

FIG. 7 shows a plot of a mean squared error against numbers of iteration in a neural network for classification of MER signals according to one embodiment of the present invention.

FIG. 8 shows a flowchart of classification of MER signals with more than one neural network according to one embodiment of the present invention.

FIG. 9 shows raw MER signals (left panels) and its decomposed MER signals (right panels), (A)-(E) corresponding to the raw and processed MER signals of different epochs, respectively.

### DETAILED DESCRIPTION OF THE INVENTION

The present invention is more particularly described in the following examples that are intended as illustrative only since numerous modifications and variations therein will be apparent to those skilled in the art. Various embodiments of the invention are now described in detail. Referring to the drawings, like numbers indicate like parts throughout the views. As used in the description herein and throughout the claims that follow, the meaning of “a,” “an,” and “the” includes plural reference unless the context clearly dictates otherwise. Also, as used in the description herein and throughout the claims that follow, the meaning of “in” includes “in” and “on” unless the context clearly dictates otherwise. Moreover, titles or subtitles may be used in the specification for the convenience of a reader, which has no influence on the scope of the invention. Additionally, some terms used in this specification are more specifically defined below.

### DEFINITIONS

The terms used in this specification generally have their ordinary meanings in the art, within the context of the invention, and in the specific context where each term is used.

Certain terms that are used to describe the invention are discussed below, or elsewhere in the specification, to provide additional guidance to the practitioner in describing various embodiments of the invention and how to practice the invention. For convenience, certain terms may be highlighted, for example using italics and/or quotation marks. The use of highlighting has no influence on the scope and meaning of a term; the scope and meaning of a term is the same, in the same context, whether or not it is highlighted. It will be appreciated that the same thing can be said in more than one way. Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification, including examples of any terms discussed herein, is illustrative only, and in no way limits the scope and meaning of the invention or of any exemplified term. Likewise, the invention is not limited to various embodiments given in this specification.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, the term “living subject” refers to a human being such as a patient, or an animal such as a lab testing monkey.

As used herein, the term “class” refers to a neuronal structure of a brain of a living subject.

As used herein, “target,” and “target region” are synonyms in the specification and refer to an area of a brain of a living subject from which a microelectrode recording signal is acquired.

### OVERVIEW OF THE INVENTION

The present invention, in one aspect, relates to a system for processing MER signals. In one embodiment, the system has means for acquiring the MER signals. Each of the MER signals is acquired from a targeted region of a brain of a living subject and is related to a neuronal structure in the targeted region of the brain of the living subject. The acquiring means in one embodiment includes at least one microelectrode recording probe, such as a platinum iridium/tungsten electrode (about 0.7 to 1.5 ohm) (Medtronic, Inc., Minneapolis, Minn.). The platinum iridium/tungsten electrode has a two channel recording unit and is placed in a target region of a brain of a living subject along a selected path. MER signals are acquired at a series of positions on the selected path by the platinum iridium/tungsten electrode. Each MER signal is acquired for about 10 second with a sample frequency of about 22 kHz. In one embodiment, the series of positions on the selected path are located at about every 0.5 mm from about −10 mm to +5 mm around the target regions, respectively. Each of the acquired MER signals includes a time domain signal. Other types of microelectrode recording probes can also be used to practice the present invention.

The system further includes a controller in communication with the acquiring means for processing the acquired MER signals. In one embodiment, the controller includes a computer. The computer is configured to perform the steps of methods, which are developed according to the various aspects of the present invention, for classifying and visualizing the MER signals. The details of the methods for classifying and visualizing the MER signals are described as follows.

Generally, MER signals of human brains are very noisy and non-stationary signals. In order to extract important features while eliminating noises or other unwanted features which obscured the ones that matter, the noises of the MER signals need to be filtered out prior to classification and visualization of the MER signals. This can be implemented by applying a wavelet de-noising algorithm to each of the MER signals. In one embodiment, the wavelet de-noising algorithm includes the step of decomposing a MER signal into multiple levels of signals, where each level of signals has an approximation coefficient and a detail coefficient. A wavelet decomposition procedure of a MER signal is described below in detail. Then the detail coefficient of each level of signals is thresholded with a corresponding threshold to produce a modified detail coefficient of the corresponding level of signals. A signal is reconstructed from approximation coefficients and modified detail coefficients of each level of signals. The reconstructed signal corresponds to a de-noising MER signal which will be utilized for classification and visualization of the MER signals. The reconstructing procedure is an inverse process of the wavelet decomposition procedure. In one embodiment, the wavelet de-noising algorithm can be performed with a Wavelet Toolbox in MATLAB 6.5 (Mathworks, Inc., Natick, Mass.).

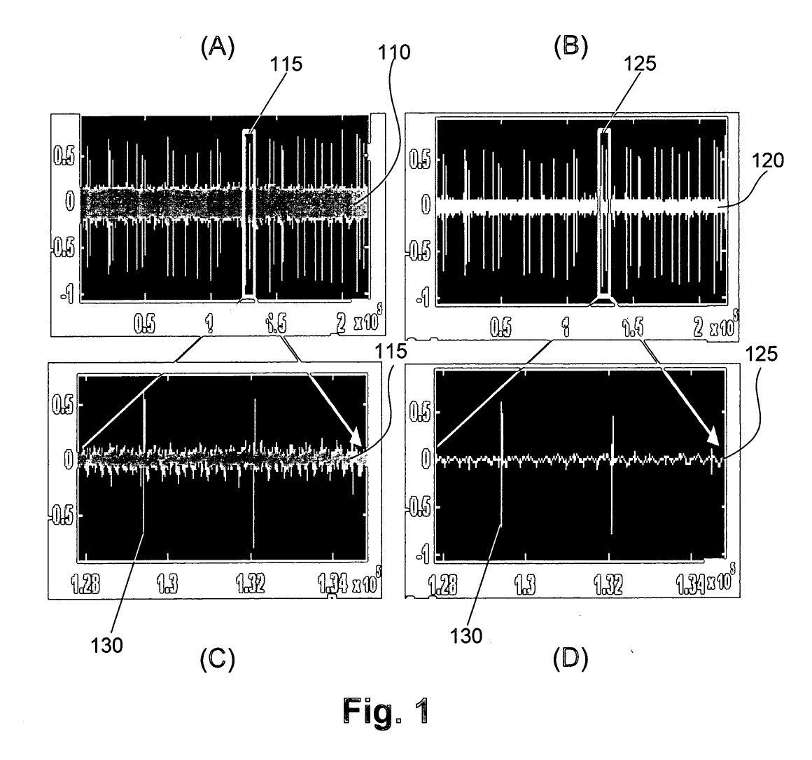

Referring to FIG. 1, a raw MER signal 110 acquired from a target of a human brain by a microelectrode probe and a de-noised MER signal 120 of the raw MER signal 110 are displayed, respectively. As is shown, the raw MER signal 110 is decomposed into five levels of signals with a Daubechies-8 mother wavelet function. Other types of mother wavelet functions can also be employed to practice the present invention. Additionally, a hard thresholding option is employed. The hard thresholding option is an algorithm for thresholding a signals and known to people skilled in the art. Zoomed views of a section 115 of the raw MER signal 110 and a section 125 of the de-noised MER signal 120 are shown in FIGS. 1C and 1D, respectively. Indeed, the wavelet de-noising decreases the noise amplitude of the raw MER signal 110 while keeping spiky nature 130 of the raw MER signal 110.

After de-noising of the raw MER signals, these de-noised MER signals are ready to be classified. In one embodiment, the method for classifying the (de-noised) MER signals includes the step of performing wavelet transforms on each of the MER signals to compute corresponding wavelet coefficients, respectively.

A wavelet transform (hereinafter “WT”) transforms a signal into a set of wavelets (basic functions) that provide information of both time and frequency of the signal and allows more accurate local description and separation of signal characteristics [7]. For a MER signal f(t), a continuous version of the WT is expressed as
C(a, b)=∫f(t)Ψ_{a,b}*(t)dt (1)
where C(a,b) is a wavelet coefficient, and

$${Ψ}_{a , b} ( t ) = \frac{1}{\sqrt{a}} Ψ ( \frac{t - b}{a} ) \qquad ( 2 )$$

is a wavelet and is a stretched and compressed versions of a mother wavelet, Ψ(t), a and b represents a scale parameter and a translation parameter, respectively. The mother wavelet Ψ(t) is used to generate all the wavelets Ψ_{a,b}(t) (a ε R and b ε R ). The translation parameter b relates to the location of the wavelet Ψ_{a,b}(t) as it is shifted through the MER signalf(t). Thus, it corresponds to the time information in the WT. The scale parameter a is defined as 1/frequency and corresponds to frequency information. Scaling either dilates (expands) or compresses the MER signalf(t). Large scales (low frequencies) dilate the MER signal and provide detailed information hidden in the MER signal f(t), while small scales (high frequencies) compress the MER signal f(t) and provide global information about the MER signal f(t). The WT on a MER signal, as described in equation (1), results in a series of wavelet coefficients C(a,b), which are a function of the scale parameter a and the position (translation) parameter b. The computation of the wavelet coefficients C(a, b) may consume significant amount of time and resources, depending on the resolution required. However, selecting scales and positions based on powers of two may yield an efficient and accurate wavelet transformation and a fast computation of the wavelet coefficients. The fast computation of wavelet coefficients can be implemented by a discrete WT.

In one embodiment, the discrete WT on a MER signal is performed with sub-band coding and/or digital filtering techniques, i.e., the MER signal to be analyzed is passed through filters with different cutoff frequencies at different scales. Specifically, a computation of wavelet coefficients of a MER signal includes the step of decomposing the MER signal into N levels of signals using a mother wavelet function. N is an integer greater than zero. The mother wavelet function serves as a filtering pattern function of the filters. The mother wavelet function in one embodiment includes a Daubechies-5 mother wavelet function. Other types of mother functions can also be employed to practice the present invention.

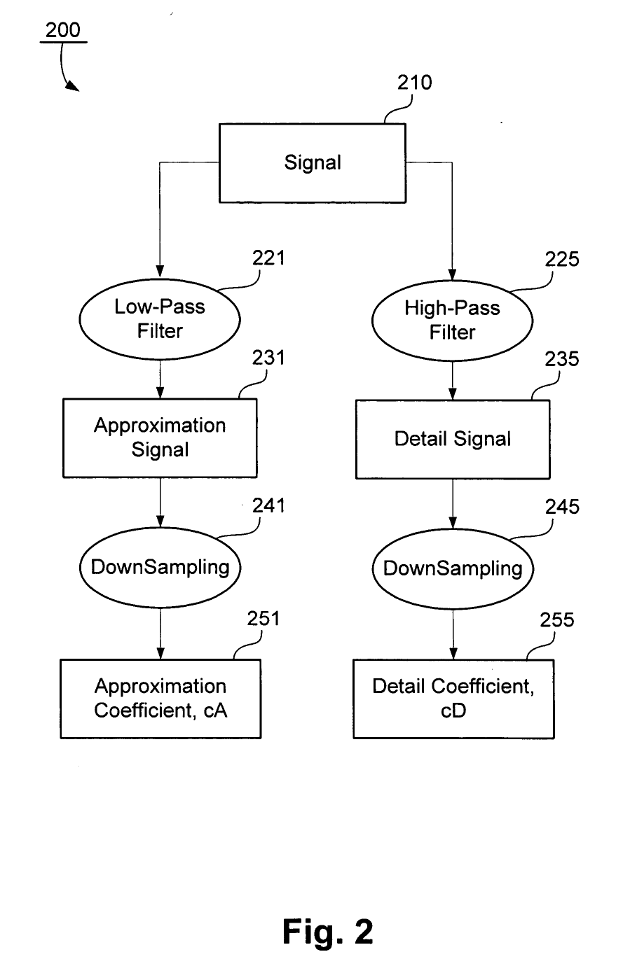

Referring now to FIG. 2, a wavelet decomposition process 200 is shown. One level of wavelet decomposition of an MER signal 210 is shown according to one embodiment of the present invention. At first, the MER signal 210 is successively filtered with a low-pass filter 221 and a high-pass filter 225 to produce an approximation signal 231 and a detail signal 235, respectively. The low-pass filter 221 has a low frequency band and the high-pass filter 225 has a high frequency band. Both the low frequency band and the high frequency band are complementary to each other in frequency. Thus, the approximation signal 231 and the detail signal 235 include low frequency information and high frequency information of the MER signal 210, respectively. However, each of the approximation signal 231 and the detail signal 235 still has same number of signal points as that of the MER signal 210. The number of signal points in the approximation signal 231 and the detail signal 235 can be reduced by performing a downsampling algorithm 241 and 245 on the approximation signal 231 and the detail signal 235, respectively. As shown in FIG. 2, downsampling 241 and 245 on the approximation signal 231 and the detail signal 235 results in an approximation coefficient 251 and a detail coefficient 255, respectively. In one embodiment, the downsampling algorithm 241 and 245 is performed with dyadic decimation such that each of the approximation coefficient 251 and the detail coefficient 255 has a half number of samples of the MER signal 210. Both the approximation coefficient 251 and the detail coefficient 255 constitute one level of decomposition of the MER signal.

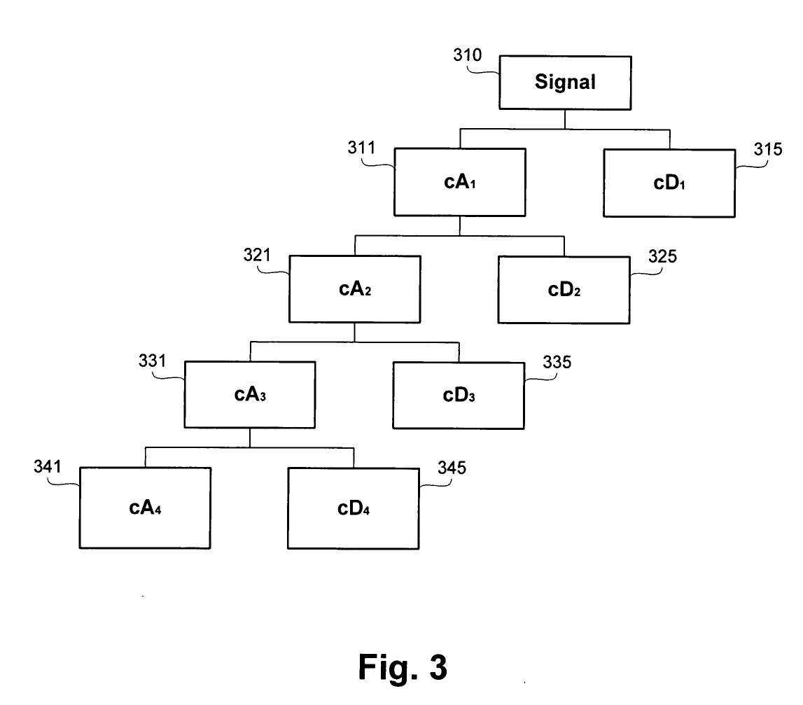

Repeating the above steps on the downsampled approximation signal N-1 times will decompose the MER signal into N levels of signals. Referring now to FIG. 3, a MER signal 310 is decomposed into 4 levels of signals. At the first level, the MER signal 310 is decomposed into a first level approximation coefficient, cA₁, 311 and a first level detail coefficient, cD₁, 315. Each of the first level approximation coefficient cA₁ 311 and the first level detail coefficient cD₁ 315 has an half of samples and an half of a frequency band of the MER signal 310. The first level approximation coefficient cA₁ 311 and the first level detail coefficient cD₁ 315 constitute the first level of signals which satisfies the relationship of cA₀=cA₁+cD₁, where cA₀ is the MER signal 310. At the second level, the first level approximation coefficient cA₁ 311 is taken as a signal to be decomposed. Applying the above wavelet decomposition procedure for constituting a first level of signal to the signal cA₁ 311 gives rise to a second level approximation coefficient, cA₂, 321 and a second level detail coefficient, cD₂, 325. Each of the second level approximation coefficient cA₂ 321 and the second level detail coefficient cD₂ 325 has an half of samples and an half of a frequency band of the signal cA₁ 311. The second level approximation coefficient cA₂ 321 and the second level detail coefficient cD₂ 325 constitute a second level of signals which satisfies the relationship of cA₁=cA₂+cD₂. Repeating the wavelet decomposition procedure at a Nth level produces a Nth level approximation coefficient, cA_{N}, and a Nth level detail coefficient, cD_{N}, so as to constitute a Nth level of signals which satisfies the relationship of cA_{N-1}=cA_{N}+cD_{N}, where cA_{N-1} is a (N-1)th level approximation coefficient. In the embodiment shown in FIG. 3, N equals to 4, i.e., the MER signal 310 is decomposed into 4 levels of signals with wavelet transformations.

Once each of the MER signals is decomposed into N levels of signals, where each level of signals is represented by an approximation coefficient and a detail coefficient. The next step of the method for classifying the MER signals according to one embodiment the current invention is to extract features from the approximation coefficients and the detail coefficients of each of the MER signals at N levels of signals. The extracted features, in one embodiment, include information of a frequency distribution of each of the MER signals, and information of an amount of changes of the frequency distribution of each of the MER signals. In one embodiment, the information of the frequency distribution comprises absolute mean values of the detail coefficients at each of N levels of signals, and the information of the amount of changes of the frequency distribution comprises standard deviations of the detail coefficients at each of N levels of signals. Then the extracted features for each of the MER signals form a corresponding vector of the extracted features. The vector of the extracted features for the corresponding MER signal represents a pattern. A pattern class is a category determined by some given attributes of patterns that are members of that class. Once a pattern representation is defined, the next step is to select a method to discriminate one class from another, i.e., pattern classification of the MER signals.

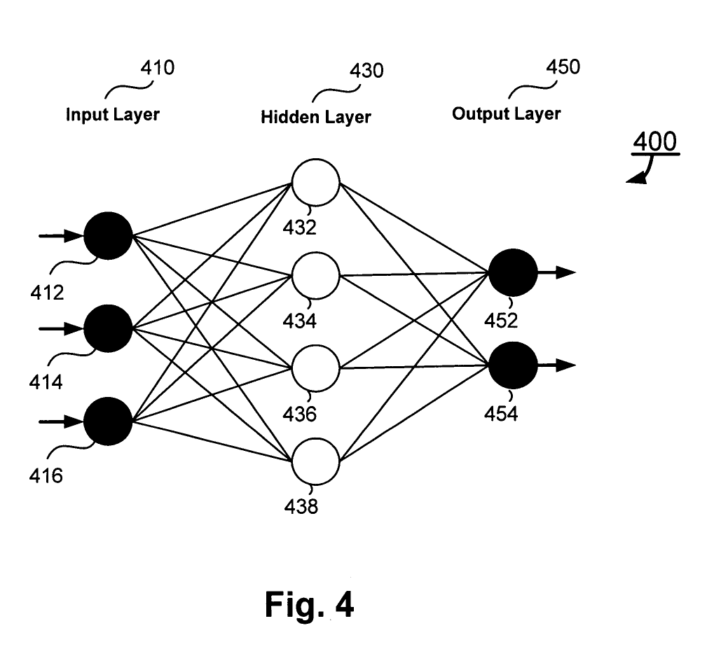

In one embodiment, the pattern classification from the extracted features of the MER signals is performed using a neural network. In one embodiment, the neural network is created with a MLP model. Referring now to FIG. 4, a typical architecture of a neural network 400 created with the MLP model is shown. The neural network 400 has an input layer 410, an output layer 450 and a hidden layer 430 formed therebetween the input layer 410 and the output layer 450. The input layer 410 has three input neurons 412, 414 and 416 that are adapted for inputting raw information (input patterns) into the neural network 400. The output layer 450 has two output neurons 452 and 454 that are adapted for outputting patterns associated with the input patterns. These input neurons 412, 414 and 416, and output neurons 452 and 454 are only connected to the adjacent layers by weights. For instance, each of input neurons 412, 414 and 416 of the input layer 410 are respectively connected only with hidden neurons 432, 434, 336, and 438 of the hidden layer 430, which, in turn, are respectively connected with each of output neurons 452 and 454 of the output layer 450. A neural network has two modes of operation: the training mode, and the testing mode. In the training mode, the neural network is trained with training data so as to associate an output pattern with a corresponding input pattern. In the testing mode, the neural network identifies the input pattern and tries to output the associated output pattern. When a taught input pattern is detected at the input, its associated output becomes the current output. If the input pattern does not belong in the taught list of input patterns, the neural network gives the output that corresponds to a taught input pattern that is least different from the input pattern. In one embodiment, a neural network that includes an input layer having 15 input neurons, a hidden layer having 21 output neurons, and an output layer having 3 output neurons is utilized to practice the present invention. Other types of neural networks, for example, a neural network having more than one hidden layer, can also be used to practice the current invention.

In one embodiment, vectors of the extracted features from the MER signals are grouped into a set of training data and a set of testing data. The set of training data is input into the neural network through the input neurons to train the neural network to associate an output pattern with a corresponding input pattern. In one embodiment, the neural network is trained with a back-propagation algorithm. The BP algorithm has two modes of operation: (1) forward propagation and (2) backward propagation. During the forward propagation mode, the set of train data is fed into the neural network through the input neurons of the input layer to produce a pattern (solution) for the output neurons of the output layer. Then, this output pattern is compared with the corresponding desired output pattern to compute the error. During the backward propagation mode, the neural network error is propagated back from the output layer to the input layer of the neural network so as to adjust the network weights. More precisely, the BP algorithm trains a neural network using a gradient descent algorithm in which the mean square error (hereinafter “MSE”) between the neural network's output pattern and the desired output pattern is minimized [8]. In another embodiment, the neural network is trained with a Levenberg-Marquardt learning algorithm [8].

After training the neural network, its performance needs to be measured on the set of testing data to evaluate how well the neural network has been trained. If the neural network is well trained, then the set of testing data is fed into the neural network through the input neurons of the input layer to identify an input pattern and to output an associated output pattern so as to discriminate one class from another of the MER signals.

In one embodiment, the performance of the neural network is measured by plotting the training curve, which displays errors of the neural network as a function of epoch. As the neural network is trained, the errors are computed and used to update the network's weights so as to enhance the performance of the neural network. The errors can be measured in different ways. In one embodiment, the measurement of the errors is the MSE. Other types of error measurements, such as normalized mean squared error (hereinafter “NMSE”), mean absolute error (hereinafter “MAE”), minimum absolute error and maximum absolute error can also be used. In another embodiment, the performance of the neural network is evaluated with a confusion matrix containing information about actual and predicted classifications classified by the neural network.

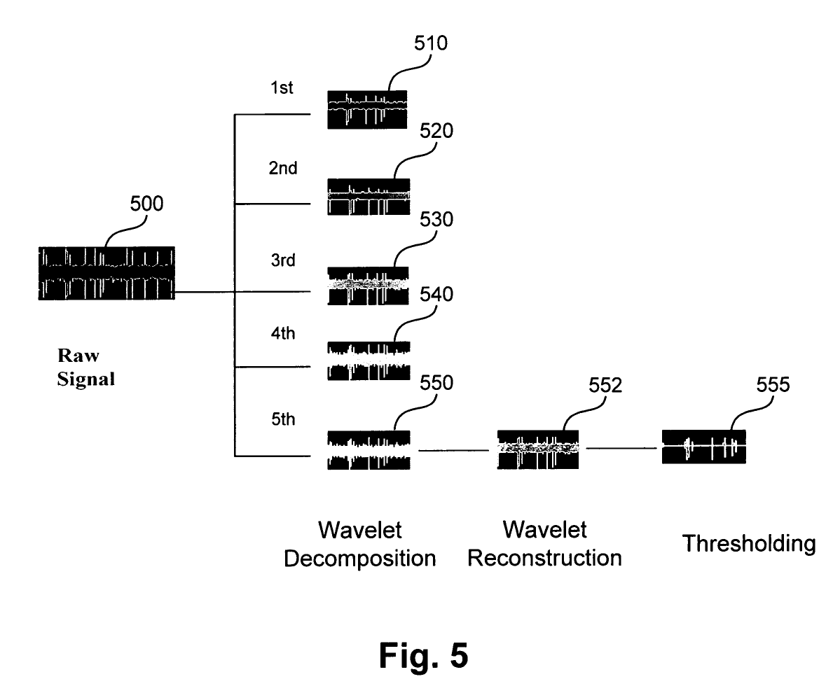

In another aspect, the present invention relates to a method for identifying a neuronal structure of a targeted region of a brain of a living subject from a MER signal that has at least one frequency band. In one embodiment, the method has the step of decomposing the MER signal into N levels of signals with a wavelet transformation. Each level of signals corresponds to a frequency band of the MER signal, and N is an integer greater than zero. The details of the wavelet decomposition algorithm are described above. Referring now to FIG. 5, a raw MER signal 500 is decomposed into five levels of signals 510, 520, 530, 540 and 550 according to one embodiment of the present invention. Then a level of signals being in the highest frequency band of the MER signal is chosen to reconstruct the MER signal. As shown in FIG. 5 and as an example, the 5th level of signals 550 is chosen. Other levels of signals can also be chosen. By applying a wavelet reconstruction algorithm to the chosen level of signals, a constructed MER signal 552 is obtained. The reconstructing algorithm is an inverse of the wavelet decomposition algorithm, as described above. Then the reconstructed MER signal 552 is thresholded to generate a signal 555, as shown in FIG. 5. The thresholded signal 555 is visualized as so to determine a neuronal structure, such as STN, of the targeted region of the brain of the living subject from the thresholded MER signal. According to the invented method, a neuronal structure, such as STN, of a targeted region of a brain of a living subject can be intro-operatively identified by visualizing the MER signal acquired from the targeted region of the brain of the living subject.

In yet another aspect, the present invention relates to software stored on a computer readable medium for causing a computing system to perform functions of classifying MER signals and/or identifying a neuronal structure of a targeted region of a brain of a living subject from a MER signal, as described above.

Without intend to limit the scope of the invention, further exemplary procedures and preliminary experimental results of the same according to the embodiments of the present invention are given below.

### IMPLEMENTATIONS AND EXAMPLES OF THE INVENTION

Pattern Classification of the MER Signals

In one embodiment of the present invention, 1889 MER signals were acquired from brains of 25 patients. Each of the MER signals was acquired from a brain of one of the 25 patients at a target point of the brain of the corresponding patient by a microelectrode recording probe, with a sampling frequency of about 22 kHz for about 10 seconds. Thus, each of the MER signals had about 2.2×10⁵ samples. The microelectrode recording probe in one embodiment included a platinum-iridium/tungsten electrode of Medtronic Inc., which had a two channel recording unit. For each patient, the corresponding MER signals were acquired at successive positions on a path, typically at every 0.5 mm from about −10 mm to about +5 mm around a target region of the patient, respectively. The path corresponded to a path of which the microelectrode recording probe passed through. An average of 70 signals per channel was recorded, with a total of 1889 electrophysiological MER signals from the 25 patients.

Then each of the 1889 MER signals was decomposed into N levels of signals with wavelet transforms according to the method of the present invention as described above, where N was an integer greater than zero. In one embodiment, N equals to five. Features for the MER signal were extracted from the decomposed five levels of signals. In one embodiment, 10 features were extracted from each of the 1889 MER signal using the wavelet decomposition, which include the absolute mean values of the detail coefficients at each of five levels of signals (totally 5 features), and the standard deviations of the detail coefficients at each of five levels of signals (totally 5 features). Besides, another five features were also included, which were a power spectrum density of the MER signal (1 feature) and four indices computed from the inter-spike interval histograms (4 features). The four indices, in one embodiment, were the burst index, pause ratio, pause index and number of detected spikes of the MER signal. For each MER signal, the 15 extracted features formed into a feature vector, which represents a pattern of the MER signal. In order to train a neural network in use for pattern classification of the MER signals, these extracted feature vectors (totally 1889 patterns) were grouped into a set of training data and a set of testing data. In one embodiment, the set of training data had about 1133 feature vectors, while the set of testing data had about 756 feature vectors, which were shown in Table 1. In this table, a Class column listed three individual classes (neuronal structures) of target regions of brains from which the MER signals were acquired. The three individual classes corresponded to STN, substantia nigra (hereinafter “SNr”) and other which was not a STN and SNr. A Training Data column listed the number of the set of training data for each of three classes, while a Testing Data column included the number of the set of testing data for each of three classes. In this embodiment, the ratio of the set of training data set and the set of testing data was about 60% to 40%.

TABLE 1
A set of testing data and a set of training data.

| Class | Training Data | Testing Data |
|---|---|---|
| STN | 232 | 132 |
| SNr | 58 | 30 |
| Other | 843 | 594 |

Accordingly, a neural network, referred to NN1 hereinafter, was created, which had the following network architecture:
Network structure: A multi-layer perceptron with an input layer, a hidden layer, and an output layer.
Inputs: 15 features including means and standard deviations of the decomposed signals (10 features), power spectrum density of MER signal (1 feature) and indices computed from the inter-spike interval histograms (4 features), where the indices were the burst index, pause ratio, pause index and number of detected spikes.
Outputs: 3 classes, which the target output values were respectively assigned as,
   [1 0 0]→Other,
   [0 1 0]→STN,
   [0 0 1]→SNr.
Transfer Functions: The tan-sigmoid function at the hidden layer and log-sigmoid function at the output layer.
Learning Method: Levenberg-Marquardt back-propagation algorithm.
Iteration Number: 1000.
Learning Rate (LR): LR=2, LR Increment=1.5, and LR Decrement=0.8
Momentum: 0.
Performance Function: MSE.

Starting with the NN1 network, the following experiments were performed to select the best neural network topology for pattern classification of the MER signals. Initially, the NN1 network was used to classify the MER signals into one of the three classes: STN, SNr, and other structures. Then, the number of hidden neurons, input neurons, output neurons, and hidden layers of the NN1 network were changed to find the best architecture for the network. Unless otherwise stated, the same set of training date and the same set of testing data, as listed in Table 1, were used to train and to test the NN1 network for each experiment. Also, weights and biases were initialized to the same initial values selected from the interval [−0.1 0.1]. All accuracy measurements of classification of the MER signals were calculated based on the set of testing data. The performance on the set of testing data was an indication of the ability of a network classifier to correctly classify MER signals that had not been seen during the training process. In one embodiment, the performance of a neural network classifier was measured by a true positive ratio (hereinafter “TP”) having a value ranging from 0 to 100. The TP ratio corresponds to a value of the number of patterns classified as positive by the neural network that were confirmed to be positive divided by the total number of confirmed positive patterns, as known to people skilled in the art.

Experiment 1

The NN1 network was first trained with the training data set. Then it was tested with the testing data set. Accordingly, the NN1 network correctly classified 77.5% of the MER signals acquired in the STN, 80.64% of the MER signals acquired in the SNr, and 93.5% of the MER signals acquired outside of these two structures, respectively. The classified results showed that STN's signals might not be well classified with the initial network topology.

Experiment 2

In this experiment, outliers were removed from the training and testing data sets as well as the missing values. In one embodiment, the training and testing data of the MER signals had 1889×15 dimensions (1889 was corresponding to the total number of data sets and 15 was corresponding to the number of extracted features). To eliminate the outliers, mean and standard deviation for a given numeric column were computed. Then, all column values either lower than (Mean−Coefficient*Standard Deviation) or higher than (Mean+Coefficient*Standard Deviation) were removed. In one embodiment, the Coefficient was set to the 2.5. The same procedure was repeated for the other columns of the training data set and the testing data set. Basically, the training data and the testing data were preprocessed by removing missing and outlier data points. Table 2 showed the number of data in the unprocessed and the preprocessed data sets. For example, in class STN, the unprocessed training data set had 232 data, while the preprocessed training data set had 212 data, thus 20 outliers had been removed from the unprocessed training data, as shown in Table 2.

Once outliers were eliminated from all the training data and testing data sets, the NN1 network was trained with the training data set, and then was tested with the testing data set in order to measure the performance of the NN1 network. It had been shown that if outliers were discarded from the training data and testing data sets, the NN1 neural network performed well for classification of STN's MER signals but not for classification of SNr's MER signals. Particularly, the TP of the STN classification increases from 75.5% to 81.98%. However, the TP of SNr's MER signals decreased from 80.64% to 75.25%. This indicated that some valuable information for classification of the SNr's signals might be lost during the outlier elimination process, which highly affected the NN1 network's performance. As shown in Table 2, significant changes in the number of the training data and testing data sets for class SNr occurred by the outlier removing process, which caused the accuracy of the SNr classification to decrease.

TABLE 2
Training and testing data sets after outliers were eliminated

| | |
|---|---|
| Unprocessed | Preprocessed |

| | Training | Testing | Training | Testing |
|---|---|---|---|---|
| Class | Data | Data | Data | Data |
| STN | 232 | 132 | 212 | 129 |
| SNr | 58 | 30 | 31 | 14 |
| Other | 843 | 594 | 810 | 564 |

In general, a large value the outlier coefficient was selected to eliminate only the most extreme data points; and a small value the outlier coefficient was used to remove all values outside of the majority. To improve the performance of the NN1 network, the outlier coefficient, Coefficient, was set to a higher value. In one embodiment, the outlier coefficient, Coefficient, was set to 5.5. The outlier elimination process as described above was repeated. Then, the NN1 network was trained and tested again with newly preprocessed data sets. The performance, in terms of TP, of the NN1 network was shown in Table 3.

As shown in Table 3, selecting a large value of the outlier coefficient worked well for all structure classification. For example, for Coefficient=2.5, the TP for the SNr's MER signals, indicating the performance of the NN1 network, was 75.25%, while it was 83.13% for Coefficient=5.5. Various values of Coefficients were evaluated, however, the best performance of the NN1 network for the MER signals was observed when the Coefficient was set to 5.5.

TABLE 3
The performance of the neural network with the
Coefficient set to 2.5 and 5.5, respectively.

| | TP | TP |
|---|---|---|
| Class | (Coefficient = 2.5) | (Coefficient = 5.5) |
| Other | 94.50% | 94.83% |
| STN | 81.98% | 80.56% |
| SNr | 75.25% | 83.13% |

Experiment 3

In this experiment, different normalization techniques were evaluated for the performance of the NN1 network for pattern classification of the MER signals. Once elimination of outliers and missing values was completed, the training data was normalized using two methods. The first method was used to scale the training data set into the range of [−1 1]. The other method was used to generate data sets that had zero mean and unity standard deviation. The same normalization techniques were applied to the testing data. The performance of the NN1 network for pattern classification of the MER signals was shown in Table 4.

TABLE 4
The performance of the NN1 network with both training and
testing data scaled to [−1 1] and normalized to zero
mean and unity standard deviation (SD), respectively.

| | | TP |
|---|---|---|
| | TP | (normalized to zero |
| Class | (scaled to [−1 1]) | mean and unity SD) |
| Other | 95.48% | 90.52% |
| STN | 83.54% | 79.23% |
| SNr | 87.94% | 80.05% |

As shown in Table 4, the performance of the NN1 network highly depended on the normalization techniques. The NN1 network had a better performance for pattern classification of the MER signals when the training data and the testing data of the MER signals were scaled to [−1, 1]. Therefore, it was preferably that the training data and testing data sets of the MER signals were normalized into the rage of [−1, 1] before classification of the MER signals.

Experiment 4

This experiment was performed to determine the best number of hidden neurons. Initially, a neural network was established with 15 input neurons and a small number of hidden neurons. Then, the number of hidden neurons was gradually increased and the performance of the network was measured. Table 5 summarized the TPs of the three classes computed for each situation. Each neural network was trained and tested with the same training data and testing data sets. Also, each experiment with a given network was repeated 8 times with different initial weight values to average over variations in performance due to initial conditions.

As shown in Table 5, if 15 features were used as an input for the neural network, the best neural network configuration was achieved with 21 hidden neurons, where the STN's MER signals were correctly classified at 87.32%, the SNr's MER signals were correctly classified at 92.41%, and other's MER signals were correctly classified at 94.15%, respectively. The performance of the neural network for pattern classification of the MER signals shown in Table 5 also indicated changes of the number of hidden neurons in the hidden layer of the neural network had little effect on the TP of the Others class, but it did had great effect on the TP of the STN and SNr classes.

Thus, it was preferable to create a multi-layer perceptron network that had an input layer having 15 input neurons, a hidden layer having 21 hidden neurons, and an output layer having 3 output neurons for classification the MER signals. The neural network was referred to NN3 hereinafter.

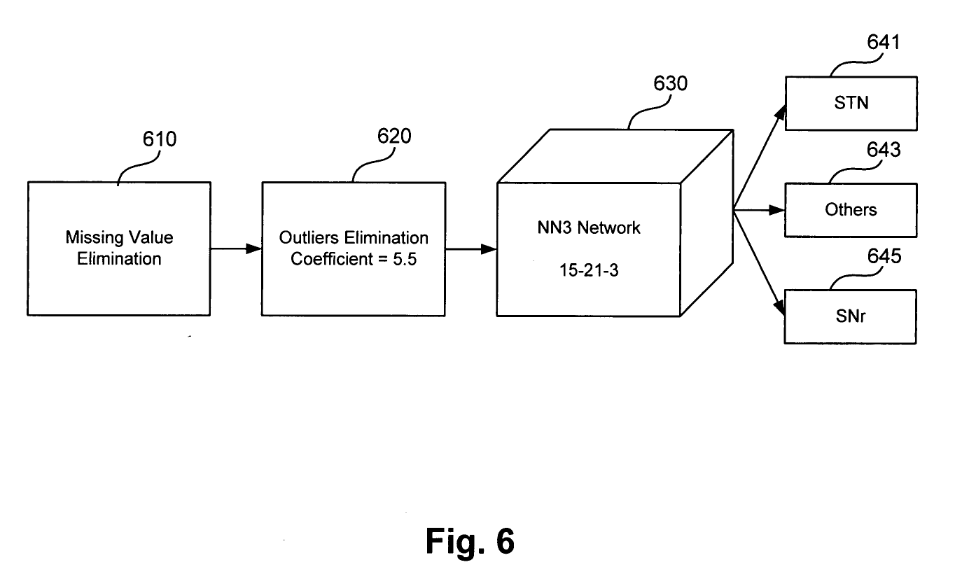

Referring now to FIG. 6, a flowchart of pattern classification of the MER signals with the NN3 network was shown according to one embodiment of the present invention. At step 610 missing values in a training data set and a testing data set of the MER signals were eliminated and outliers in the training data set and the testing data were eliminated with an outlier coefficient 5.5 at step 620 so as to produce a set of preprocessed training data and a set of preprocessed testing data, respectively. At step 630, the NN3 was trained the set of preprocessed training data and then tested with the set of preprocessed testing data so as to classify the MER signals and output its associated output pattern classes. In this embodiment shown in FIG. 6, the associated output pattern classes were STN 641, SNr 645 and others 643.

TABLE 5
The performance of NN3 networks with fifteen input
neurons and various numbers of hidden neurons.

| Number of Hidden | TP | | |
|---|---|---|---|
| Neurons | Other | STN | SNr |
| 7 | 95.48% | 83.54% | 87.94% |
| 9 | 95.33% | 82.45% | 82.22% |
| 11 | 93.44% | 80.74% | 79.98% |
| 13 | 94.15% | 75.67% | 80.01% |
| 17 | 95.74% | 83.90% | 86.06% |
| 19 | 96.45% | 85.23% | 84.03% |
| 21 | 94.15% | 87.32% | 92.41% |
| 24 | 96.45% | 84.52% | 89.63% |
| 26 | 95.39% | 78.97% | 81.09% |
| 28 | 94.50% | 79.50% | 75.30% |

Experiment 5

This experiment was performed to select the best transfer function of the input layer for the NN3 network classifer.

In one embodiment, two functions, a log-sigmoid function and a tan-sigmoid function were selected as a transfer function for the input layer, respectively. Initially, the NN3 network was trained with the training data set. It was then tested with the testing data set. Table 6 shows the TP ratios of classes when two different transfer functions were used. For each experiment, the NN3 network was trained with the same data sets and its weights and biases were initalized to same initial value.

TABLE 6
The performance of the NN3 network with log-sigmoid and tan-sigmoid
transfer function for the input layer, respectively.

| | TP | TP |
|---|---|---|
| | (with a log- | (with a tan- |
| Class | sigmoid function) | sigmoid function) |
| Other | 95.61% | 95.27% |
| STN | 83.94% | 87.59% |
| SNr | 88.46% | 92.30% |

As shown in Table 6, for STN and SNr classifications of the MER signals by the NN3 network classifier, the tan-sigmoid function for the input layer was more suitable than the log-sigmoid function.

Experiment 6

In this experiment, the network was trained with the scaled conjugate gradient algorithm (hereinafter “trainscg”), the Polak-Ribiere conjugate gradient algorithm (hereinafter “traincgp”) as well as the LM algorithm. In each case, the NN3 network's weights and biases were initialized to the same initial values. The results were shown in Table 7.

TABLE 7
The performance of the NN3 network when the network
was trained with the traincgp, the trainscg and LM

| | TP | TP | TP |
|---|---|---|---|
| | (with the trainscg | (with the traincgp | (with the LM |
| Class | algorithm) | algorithm) | algorithm) |
| Other | 94.43% | 94.77% | 94.27% |
| STN | 78.83% | 80.29% | 87.12% |
| SNr | 84.61% | 80.76% | 92.41% |

As indicated in Table 7, the LM algorithm provided the best results for the pattern classification of the MER signals by the NN3 network classifier when compared to the others.

Experiment 7

Another important issue for the neural network classification was that the training data points should be carefully chosen to reflect the range and magnitude of the inputs and outputs in order to develop a neural network with good classification capability. In this experiment, tne different training and testing data sets were used. For each experiment, the NN3 netweoks's weights and biases were initialized to the same initial value. The computed TP ratios were given in Table 8.

TABLE 8
The performance of the NN3 network when the Network
was trained and tested with different data sets.

| | TP (%) | | |
|---|---|---|---|
| Data Set | Other | STN | SNr |
| 1 | 94.15% | 87.32% | 92.41% |
| 2 | 95.27% | 87.59% | 92.30% |
| 3 | 93.50% | 83.45% | 93.64% |
| 4 | 94.45% | 86.30% | 91.46% |
| 5 | 95.60% | 82.46% | 89.50% |
| 6 | 96.64% | 87.75% | 88.36% |
| 7 | 96.50% | 86.53% | 90.50% |
| 8 | 94.32% | 81.16% | 90.00% |
| 9 | 93.26% | 87.38% | 80.36% |
| 10 | 95.50% | 86.64% | 92.00% |

As shown in Table 8, the best performance was obtained when the second data set was used. For this data set, the STN, SNr and Other were correctly classified at 87.59%, 92.64% and 95.27%, respectively. A relatively low TP ratio for the STN and the SNr were obtained with the 8th and 9th data sets, respectively. In these instances, important signal patterns appreard in the testing sets but were not represented in the training set and were misclassified.

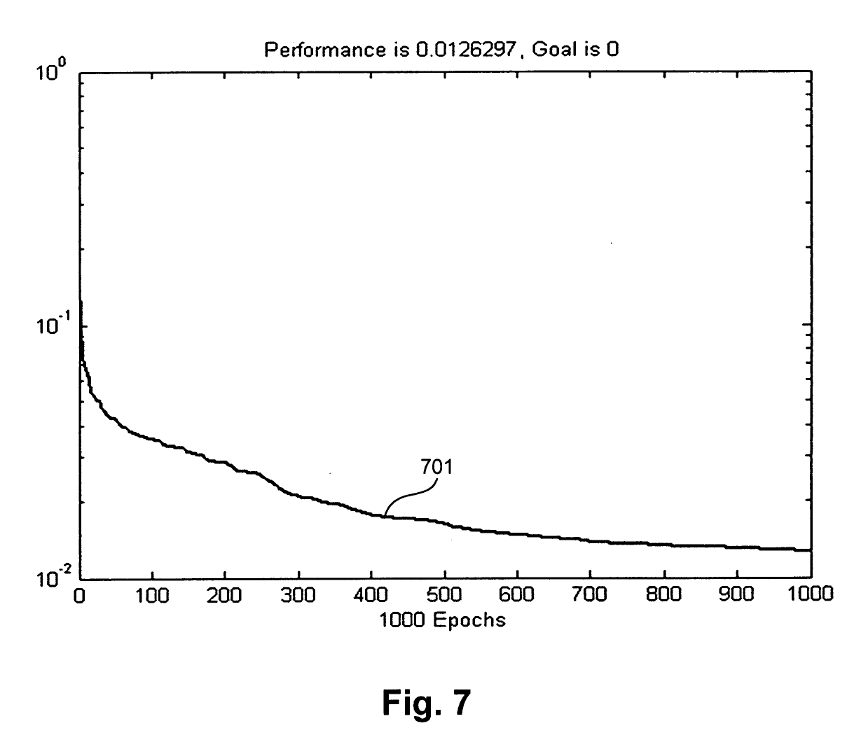

Referring now to FIG. 7, a training curve 701 of the MSE as a function of the number of iteration was shown. The training curve 701 was obtained with the second data set. As shown in FIG. 7, the input had been presented to the NN3 network until a pre-defined number of iterations had been reached. The MSE was 0.0126 after the NN3 network had been trained for 1000 times.

TABLE 9
Confusion matrix computed for the NN3 network that
were trained and tested with the second data set.

Network Output

| | Class | Other | STN | SNr |
|---|---|---|---|---|
| Desired | Other | 565 | 22 | 6 |
| Output | STN | 10 | 120 | 7 |
| | SNr | 1 | 1 | 24 |

Table 9 showed a confusion matrix computed for the NN3 network that had been trained and tested with the second data set. A confusion matrix is a square matrix whose rows, i, and columns, j, represent a desired outputs and network outputs, respectively. The value in the (i, j) cell of the confusion matrix is the number of values of the network outputs in the jth category and whose desired output is within the ith category. Ideally, the actual network outputs and desired outputs should be same, and a perfect classification is obtained if one obtains zeros everywhere except on the diagonal entries. For example in Table 9, the value 120 of the cell (STN, STN) indicated the number of the network outputs in the STN class and whose desired output is within the STN class, while the value 7 of the cell (STN, SNr) represented the number of the network outputs in the STN class and whose desired output is within the SNr class.

Table 10 showed a statistically analysis of the confusion matrix which represented the performance of the NN3 network for pattern classification of the MER signals. In Table 10, each value of the diagonal cells was a TP for a corresponding class to be correctly classified, and a sum of the other two values in the class row indicated a percentage of the class that had been incorrectly classified. As shown in Table 10, the STN was correctly classified at 87.59% and incorrectly classified at (7.29% )+5.1%)=12.39%; the SNr was correctly classified at 92.3% and incorrectly classified at (3.84%+3.84%)=7.68%. The results by using other network structures as shown in Table 10 showed that the MER signals were correctly classified into other at 95.27%, and were incorrectly classified other at (3.7%+1.01%)=4.71%. The correct classification rate (CCR) was 93.78%.

TABLE 10
Confusion matrix computed for the NN3 network that had been trained
and tested with the 2nd data set (shown in percentage).

| | Network Output | | | | |
|---|---|---|---|---|---|
| | Class | Other | STN | SNr | CCR |
| Desired | Other | 95.27% | 3.7% | 1.01% | |
| Output | STN | 7.29% | 87.59% | 5.1% | |
| | SNr | 3.84% | 3.84% | 92.3% | 93.78% |

In brief, as described above, the best performance of a neural network for pattern classification of the MER signals was achieved with a neural network topology, which included the NN3 architecture having a tan-sigmoid function at the hidden layer and a log-sigrnoid function at the output layer. The learning method of the NN3 network included the Levenberg-Marquardt back-propagation algorithm with about 1000 times of iteration. The learning rate (LR) of the NN3 network included LR=2, LR Increment=1.5, and LR Decrement=0.8. And the performance function of the NN3 network included MSE.

Experiment 8

In this experiment, a different approach was taken. A neural network, referred to NN4 hereinafter, was created with 15 input units, 7 hidden units and 2 output units so that it could classify only two classes. The NN4 network was trained with the training data set and then tested with the testing data set. The NN4 network correctly classified 90.5% of the signals acquired in the STN, and 96.5% of the signals acquired outside of these two structures (STN and SNr).

The NN4 network was also used to classify the MER signals into one of two classes: Others and SNr. The NN4 network was trained and tested with the same data set used in the previous step. The SNr and Other structures' signals were correctly classified 93.6% and 97.1%, respectively.

These results from the NN4 network classification demonstrated that a two-class classifier was better than a three-class classifier in the pattern classification of the MER signals.

Experiment 9

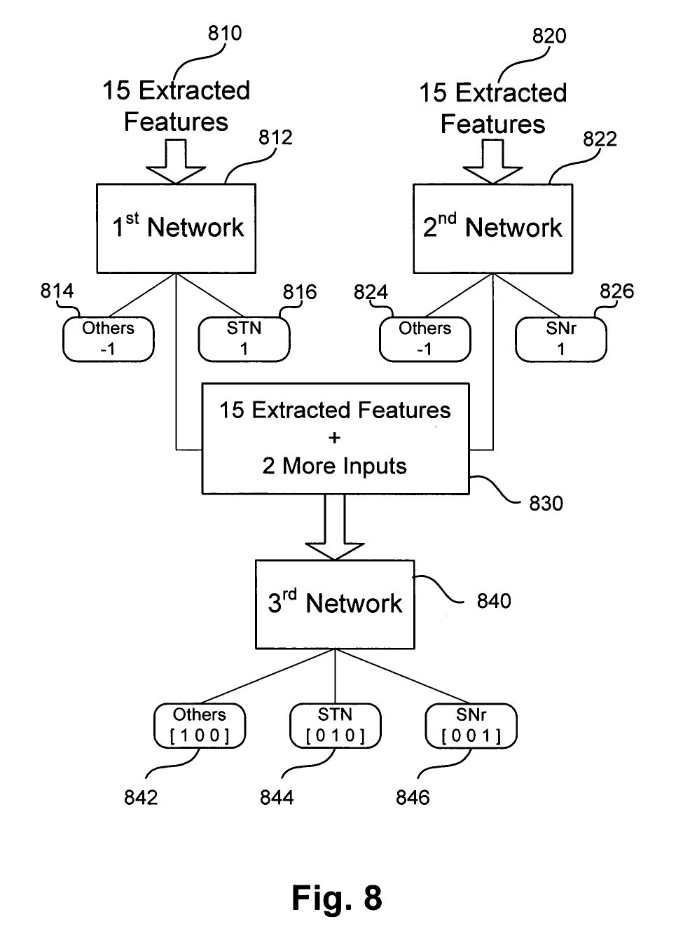

In one embodiment of the present invention, the classification of the MER signals can be performed with more than one neural network. In this experiment, three networks were created for classification of the MER signals. As shown in FIG. 8, the first network 812 was used to classify 15 extracted features 810 of the MER signals into one of the two classes: STN 816 and Others 814. The second network 822 was created for classifying 15 extracted features of the MER signals into the SNr 826 or the Other structures 824. The outputs of the first network and the second network were combined with the 15 extracted features to become an enhanced 17 feature input 830 and it was fed to the third network 840. The third network 840 was designed for classifying the combined 17 features of the MER signals into the STN 844, the SNr 846, and the other 842 classes. The network topology of the NN4 network was used for the first and second networks while the third network topology was the same as the NN3 network's topology, except that the input neurons were 17 instead of 15.

Initially, inputs and outputs were collected. Fifteen features were used as an input data for all networks. The input data was preprocessed before being fed to the networks by applying the missing values and outlier elimination process detailed in earlier experiment. Target output values for each network were defined as:
First Network: STN→0 and Other/SNr→1
Second Network: SNr→0 and Other/STN→1
Third Network: Other [1 0 0], STN→[0 1 0], SNr [0 0 1]

After training the first and the second networks with the training data set in Table 2, outputs of the first and second network were fed to the third network as new inputs combined with the 15 features from the MER signals.

The system correctly classified 87.5% of the signals acquired in the STN, 91.5% of the signals acquired in the SNR, and 94.6% of the signals acquired outside of these two structures.

Pattern Classification with Different Methods

In one embodiment, a pattern classification of MER signals was performed using different types of features. The different types of features were extracted from the MER signals with different methods. One method was to decompose each of the MER signals into five levels of signals with the wavelet transformation and extract features from the decomposed MER signal. The extracted feature for the MER signal included mean values of detail coefficients at each of five levels of signals (totally 5 features), and standard deviations of detail coefficients at each of five levels of signals (totally 5 features). The totally 10 extracted features formed one type of extracted features which was referred to WD) features hereinafter.

In this embodiment, 1643 MER signals were classified using the W/D features with a MLP network having an input layer, a hidden layer and an input layer. The input layer, the hidden layer and the input layer had 10 input neurons, 5 hidden neurons and one output neuron, respectively. The 10 WD features were fed into the network through the 10 input neurons, and the output neuron output one class, STN or other neuronal structure. The transfer function of the network included a tan-sigmoid function at the hidden layer and a log-sigmoid function at the output layer. The learning method of the network included the Levenberg-Marquardt back-propagation algorithm. The 1643 MER signals were grouped into a set of training data, 1117, and a set of testing data, 526. The network was trained with the set of training data and then tested with the set of testing data. The performance for the pattern classification of the 1643 MER signals was shown in a WD Feature column of Table 11, where the STN was correctly classified at TP=89.10% and incorrectly classified at FN=10.89%. An overall agreement rate was 92.8%. The agreement rate was calculated by using the following equation:

$$Agreement Rate = 100 * \frac{( TN + TP )}{( TN + TP + FP + FN )} , \qquad ( 3 )$$

where TP, FP, TN, FN are true-positive ratio, false-positive ratio, true-negative ratio, false-negative ratio, respectively, and known to people skilled in the art.

TABLE 11
The performance of network classification
of the MER signals with different methods.

| | |
|---|---|
| WD Features | ST-PSD Features |

| Performance | STN | Other | STN | Other |
|---|---|---|---|---|
| True Positive | 89.10% | 96.50% | 70.29% | 90.69% |
| Ratio (TP) | | | | |
| False Positive | 3.47% | 10.89% | 9.30% | 29.70% |
| Ratio (FP) | | | | |
| True Negative | 96.50% | 89.10% | 90.69% | 70.29% |
| Ratio (TN) | | | | |
| False Negative | 10.89% | 34.7% | 29.70% | 9.30% |
| Ratio (FN) | | | | |

| | | |
|---|---|---|
| Agreement Rate | 92.8% | 80.49% |
| (AR) | | |

As a comparison of the WD feature classification of the MER signals, another type of features of the MER signals was used to classify patterns of the MER signals. The type of features included 8 features extracted with spike train and power spectrum density of the MER signals and referred to ST-PSD features hereinafter. The classification results of the MER signals using the ST-PSD features were shown in a ST-PSD Features column of Table 11. The STN was correctly classified at TP=70.29% and incorrectly classified at FN=29.70%. An overall agreement rate was 80.49%.

In summary, WD features extracted from the MER signals with the wavelet decomposition provide acceptable performance to differentiate neuronal structures such as STN more consistently and more precisely. The agreement rate for correct classification of neuronal structures using the WD features was increased from 80.49% (using ST-PSD features) to 92.8%.

Visualization of MER Signals

The present invention, among other unique things, relates to an intra-operative visualization technique for a MER brain signal to determine neuronal structure, such as STN, from which the MER signal was acquired. In one embodiment, the MER signal was decomposed into five levels of signals by performing wavelet decomposition on the MER signal. Only the fifth component of the decomposed signals was considered. This fifth component was in the highest frequency band. Then, the signal from these coefficients was reconstructed with a wavelet reconstruction algorithm. The reconstructed signal was threshold and displayed.

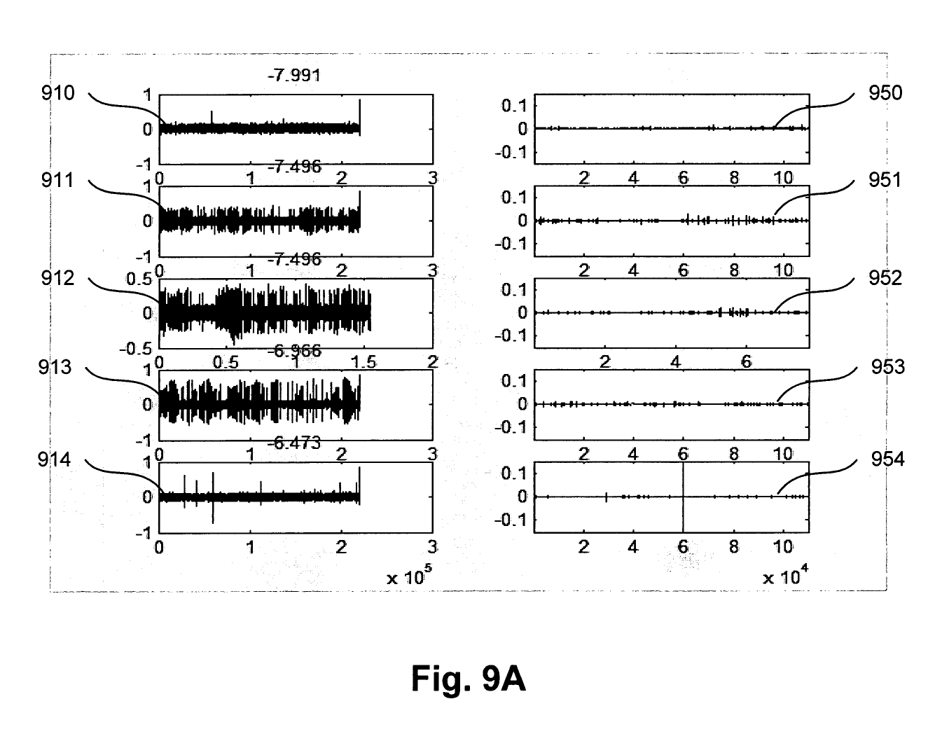

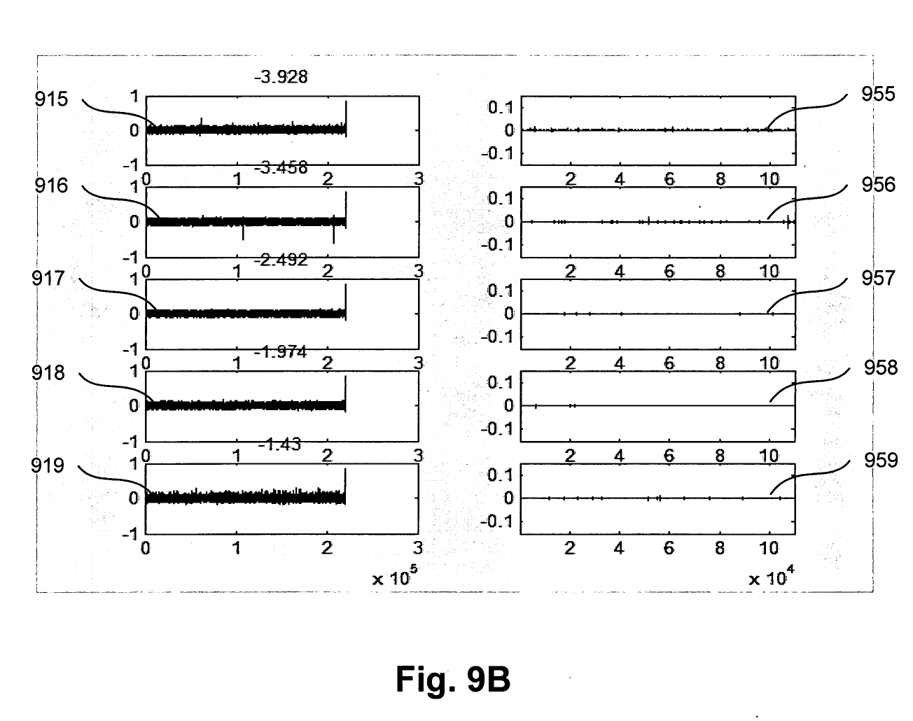

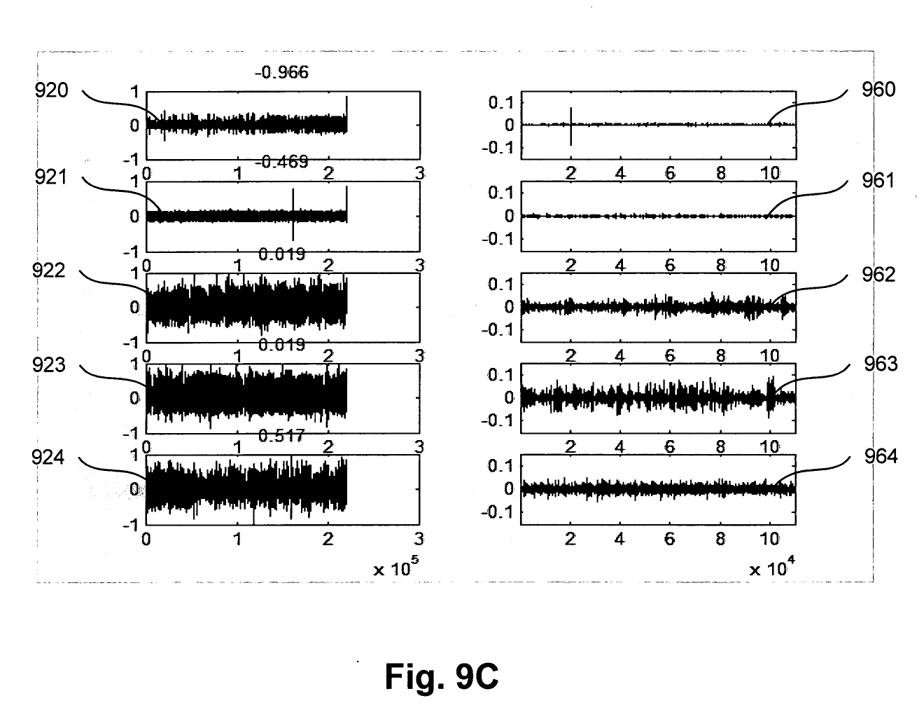

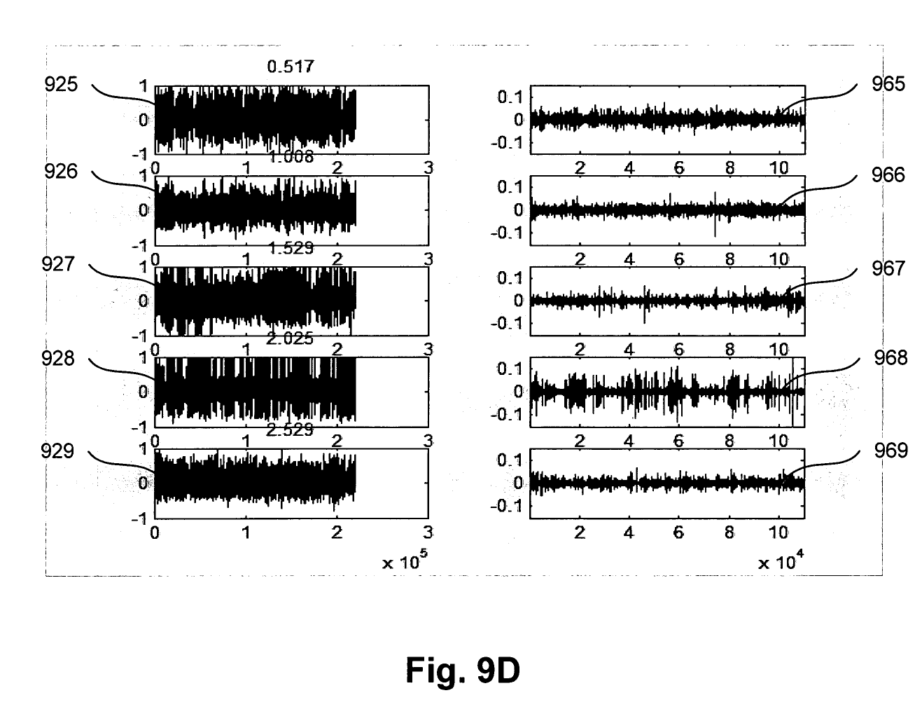

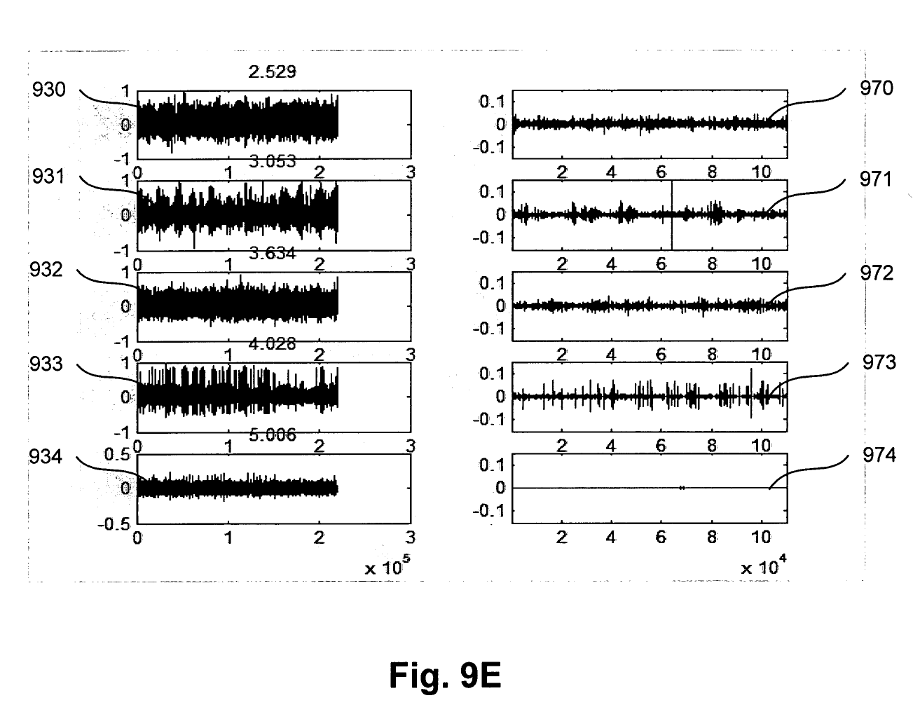

Referring now to FIGS. 9A-9E, signals 910-934 were corresponding to 25 MER signals which were epochs that had been recorded along a microelectrode probe path in a brain of a patient, and signals 950-974 were corresponding processed signals of signals 910-934, respectively. Signals 910-921 and 934 were acquired outside the STN, while signal 922-933 were recorded inside the STN. As shown in FIGS. 9A-9E, when the MER signals were acquired from outside the STN, for example, signals 910-921 and 934, the corresponding processed signals 950-961 and 974 were almost zero. When the MER signals such as signals 922-933 were acquired inside the STN, the corresponding processed signals 962-973 varied significantly. This visualization technique enabled neurosurgeons to easily distinguish the STN from other structures even when MER signals came from other neuronal structures producing STN-like MER signals, for example signals 911-913.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

### LIST OF REFERENCES

[1]. G. Deuschl, J. Volkmann, and P. Krack, “Deep brain stimulation for movement disorders”, Movement Disorders, vol. 17 (supplement 3), pp S1-S1, 2002.
[2]. B. Schrader, W. Hamel, D. Weinert, and H. M. Mehdorn, “Documentation of electrode localization.” Movement Disorders, vol. 17 (supplement 3), pp S167-S174, 2002.
[3]. P. A. Starr et al., “Implantation of deep brain stimulators into the subthalamic nucleus: technical approach and magnetic resonance imaging—verified lead locations,” J. Neurosurgery, vol. 97, pp. 370-387, 2002.
[4]. J. Guridi, A. Gorospe, E. Ramos, G. Linazasoro, M. C. Rodriguez, and J. A. Obeso, “Stereotactic targeting of the globus pallidus intemus in Parkinson's disease:

imaging versus electrophysiological mapping,” Neurosurgery, vol. 45, pp. 278-289 1999.
[5]. J. Favre, J. M. Taha, T. Baumann, and K. J. Burchiel, “Computer analysis of the tonic, phasic, and kinesthetic activity of pallidal discharges in Parkinson patients,” Surg Neurol, vol. 51, pp. 665-673, 1999.
[6]. J. H. Falkenberg, J. McNames, M. Aboy, K. J. Burchiel, “Segmentation of Extracellular Microelectrode Recordings with Equal Power,” Ann. Int. Conf. of the IEEE Eng. in Medicine and Biology—Proceedings, Cancun, Mexico, pp. 2475-2478, 2003.
[7]. G. Tzanetakis, G. Essl, and P. Cook, “Audio Analysis using the Discrete Wavelet Transform,” In. Proc. WSES Int. Conf. Acoustics and Music: Theory and Applications (AMTA 2001), Skiathos, Greece, 2001.
[8]. M. T. Hagan, M. B. Menhaj, “Training Feedforward Networks with the Marquart Algorithm,” IEEE Trans. on NN, vol. 5, no. 6, pp. 986-93, 1994.

1. A method for classifying microelectrode recording signals, comprising the steps of:
a. performing wavelet transforms on each of the microelectrode recording signals to compute corresponding wavelet coefficients, respectively;
b. extracting features from the computed wavelet coefficients for each of the microelectrode recording signals, respectively; and
c. classifying the extracted features so as to classify the microelectrode recording signals.

2. The method of claim 1, wherein each of the microelectrode recording signals is acquired from a targeted region of a brain of a living subject.

3. The method of claim 2, wherein each of the microelectrode recording signals comprises a time domain signal.

4. The method of claim 3, wherein each of the microelectrode recording signals is related to a neuronal structure in the targeted region of the brain of the living subject.

5. The method of claim 1, wherein the performing step comprises the step of decomposing each of the microelectrode recording signals into N levels of signals, N being an integer greater than zero.

6. The method of claim 5, wherein the decomposing step comprises the steps of:
a. filtering a microelectrode recording signal into an approximation signal and a detail signal with a low-pass filter and a high-pass filter, respectively, wherein a low-pass filter and a high-pass filter are complementary to each other in frequency;
b. downsampling the approximation signal and the detail signal to produce an approximation coefficient and a detail coefficient, respectively, wherein both the approximation coefficient and the detail coefficient constitute one level of decomposition of the microelectrode recording signal; and
c. repeating steps (a) and (b) on the downsampled approximation signal N-1 times so as to decompose the microelectrode recording signal into N levels of signals such that a first level, a second level, . . . , and a Nth level of signals comprise cA₀=cA₁+cD₁, cA₁=cA₂+cD₂, . . . , and cA_{N-1}=cA_{N}+cD_{N}, respectively, wherein cA₀ corresponds to the microelectrode recording signal, cA₁, cA₂, . . . , and cA_{N} are approximation coefficients of the first level, the second level, . . . , and the Nth level of signals, respectively, and cD₁, cD₂, . . . , and cD_{N} are detail coefficients of the first level, the second level, . . . , and the Nth of signals, respectively.

7. The method of claim 6, wherein the downsampling step is performed with dyadic decimation such that each of an approximation coefficient cAⱼ and an detail coefficient cDⱼ at a jth level has an half number of samples of a (j-1)th level of signals, wherein j=1, 2, . . . , N.

8. The method of claim 6, wherein the performing step is performed with a mother wavelet function.

9. The method of claim 8, wherein the mother wavelet function comprises a Daubechies-5 mother wavelet function.

10. The method of claim 6, wherein the extracted features comprise:
a. information of a frequency distribution of each of the microelectrode recording signals; and
b. information of an amount of changes of the frequency distribution of each of the microelectrode recording signals.

11. The method of claim 10, wherein the information of the frequency distribution comprises absolute mean values of the detail coefficients at each of N levels of signals, and wherein the information of the amount of changes of the frequency distribution comprises standard deviations of the detail coefficients at each of N levels of signals.

12. The method of claim 11, further comprising the step of forming a vector of the extracted features for each of the microelectrode recording signals, wherein the vector of the extracted features corresponds to a pattern.

13. The method of claim 12, further comprising the step of creating a neural network having an input layer, an output layer and at least one hidden layer formed therebetween the input layer and the output layer.

14. The method of claim 13, wherein the input layer has at least one neuron adapted for inputting patterns, and the output layer has at least one neuron adapted for outputting patterns corresponding to the input patterns, respectively.

15. The method of claim 14, wherein the neural network is created with a multi-layer perceptron model.

16. The method of claim 14, wherein the classifying step comprises the steps of:
a. grouping vectors of the extracted features into a set of training data and a set of testing data, respectively;
b. training the neural network with the set of training data so as to associate an output pattern with a corresponding input pattern; and
c. testing the neural network with the set of testing data so as to identify an input pattern and to output an associated output pattern.

17. The method of claim 16, wherein the classifying step is performed with a Levenberg-Marquardt back-propagation algorithm.

18. The method of claim 1, further comprising the step of de-noising each of the microelectrode recording signals, respectively.

19. The method of claim 18, wherein the de-noising step comprises the steps of:
a. decomposing a microelectrode recording signal into multiple levels of signals, wherein each level of signals comprises an approximation coefficient and a detail coefficient;
b. thresholding the detail coefficient of each level of signals with a corresponding threshold to produce a modified detail coefficient of the corresponding level of signals; and
c. reconstructing the microelectrode recording signal from approximation coefficients and modified detail coefficients of each level of signals.

20. An apparatus for classifying microelectrode recording signals, comprising a controller performing the steps of:
a. performing a wavelet transform on each of the microelectrode recording signals to compute corresponding wavelet coefficients, respectively;
b. extracting features from the computed wavelet coefficients for each of the microelectrode recording signals, respectively; and
c. classifying the extracted features so as to classify the microelectrode recording signals.

21. The apparatus of claim 20, further comprising means for acquiring the microelectrode recording signals.

22. The apparatus of claim 21, wherein the acquiring means is in communication with the controller.

23. The apparatus of claim 22, wherein the acquiring means comprises at least one microelectrode recording probe placed in a target region of a brain of a living subject.

24. The apparatus of claim 20, further comprising a neural network communicating with the controller and having an input layer, an output layer and at least one hidden layer formed therebetween the input layer and the output layer.

25. The apparatus of claim 24, wherein the input layer has at least one neuron adapted for inputting patterns, and the output layer has at least one neuron adapted for outputting patterns corresponding to the input patterns.

26. The apparatus of claim 25, wherein the neural network is created with a multi-layer perceptron model.

27. The apparatus of claim 20, wherein the controller comprises a computer.

28. Software stored on a computer readable medium for causing a computing system to perform functions comprising:
a. performing wavelet transforms on each of microelectrode recording signals acquired from a targeted region of a brain of a living subject to compute corresponding wavelet coefficients, respectively;
b. extracting features from the computed wavelet coefficients for each of the microelectrode recording signals, respectively; and
c. classifying the extracted features so as to classify the microelectrode recording signals.

29. A method for identifying a neuronal structure of a targeted region of a brain of a living subject from a microelectrode recording signal that has at least one frequency band, comprising the steps of:
a. decomposing the microelectrode recording signal into N levels of signals with a wavelet transformation, each level of signals corresponding to a frequency band of the microelectrode recording signal, and N being an integer greater than zero;
b. choosing a level of signals which is in the highest frequency band of the microelectrode recording signal;
c. reconstructing the microelectrode recording signal from the chosen level of signals;
d. thresholding the reconstructed microelectrode recording signal; and
e. determining a neuronal structure of the targeted region of the brain of the living subject from the thresholded microelectrode recording signal.

30. The method of claim 29, wherein the microelectrode recording signal is acquired from the targeted region of the brain of the living subject for a predetermined period of time.

31. The method of claim 30, wherein the microelectrode recording signals is related to a neuronal structure in the targeted region of the brain of the living subject.

32. The method of claim 29, further comprising the step of visualizing the thresholded microelectrode recording signal.

33. The method of claim 29, wherein the reconstructing step is performed with an inverse of the wavelet transformation.

34. The method of claim 29, wherein the chosen level of signals comprises a Nth level of signals.

35. The method of claim 34, wherein N equals to 5.

36. An apparatus for identifying a neuronal structure of a targeted region of a brain of a living subject from a microelectrode recording signal that has at least one frequency band, comprising
a controller performing the steps of:
a. decomposing the microelectrode recording signal into N levels of signals with a wavelet transformation, each level of signals corresponding to a frequency band of the microelectrode recording signal, and N being an integer greater than zero;
b. choosing a level of signals which is in the highest frequency band of the microelectrode recording signal;
c. reconstructing the microelectrode recording signal from the chosen level of signals;
d. thresholding the reconstructed microelectrode recording signal; and
e. determining a neuronal structure of the targeted region of the brain of the living subject from the thresholded microelectrode recording signal.

37. The apparatus of claim 36, further comprising means for acquiring the microelectrode recording signal from the targeted region of the brain of the living subject for a predetermined period of time.

38. The apparatus of claim 37, wherein the acquiring means is in communication with the controller.

39. The apparatus of claim 38, wherein the acquiring means comprises at least one microelectrode recording probe placed in the targeted region, of the brain of the living subject.

40. The apparatus of claim 39, wherein the at least one microelectrode recording probe comprises at least one channel.

41. The apparatus of claim 40, wherein the microelectrode recording signal is related to an anatomical structure in the targeted region of the brain of the living subject.

42. The apparatus of claim 36, further comprising at least one display for visualizing the thresholded microelectrode recording signal.

43. The apparatus of claim 42, wherein the at least one display is in communication with the controller.

44. The apparatus of claim 36, wherein the controller comprises a computer.

45. Software stored on a computer readable medium for causing a computing system to perform functions comprising:
a. decomposing a microelectrode recording signal acquired from a targeted region of a brain of a living subject into N levels of signals with a wavelet transformation, each level of signals corresponding to a frequency band of the microelectrode recording signal, and N being an integer greater than zero;
b. choosing a level of signals which is in the highest frequency band of the microelectrode recording signal;
c. reconstructing the microelectrode recording signal from the chosen level of signals;
d. thresholding the reconstructed microelectrode recording signal; and
e. determining a neuronal structure of the targeted region of the brain of the living subject from the thresholded microelectrode recording signal.

46. A method for feature extraction of at least one non-stationary signal, comprises the steps of:
a. performing a wavelet transform on the at least one non-stationary signal to compute corresponding wavelet coefficients; and
b. extracting features from the computed coefficients.

47. The method of claim 46, wherein the at least one non-stationary signal comprises a microelectrode recording signal acquired from a targeted region of a brain of a living subject.

48. The method of claim 47, wherein the microelectrode recording signal is related to a neuronal structure in the targeted region of the brain of the living subject.

49. The method of claim 46, wherein the performing step comprises the step of discriminating between the at least one non-stationary signal with different frequency features.

50. The method of claim 46, wherein the performing step comprises the steps of decomposing the at least one non-stationary signal into N levels of signals, each level of signals comprising an approximation coefficient and a detail coefficient and corresponding to a frequency band of the at least one non-stationary signal, and N being an integer greater than zero.

51. The method of claim 50, further comprising the step of:
a. choosing a level of signals which is in the highest frequency band of the at least one non-stationary signal;
b. reconstructing the at least one non-stationary signal from the chosen level of signals;
c. thresholding the reconstructed signal; and
d. visualizing the thresholded signal.

52. The method of claim 50, wherein the extracted features comprise:
a. information of a frequency distribution of the at least one non-stationary signal; and
b. information of an amount of changes of the frequency distribution of the at least one non-stationary signal.

53. The method of claim 52, further comprising the step of classifying the extracted features.

54. The method of claim 53, wherein the classifying step is performed within a neural network.

55. The method of claim 54, wherein the neural network is created with a multi-layer perceptron model.

56. The method of claim 55, wherein the classifying step is performed with a Levenberg-Marquardt back-propagation algorithm.

57. Software stored on a computer readable medium for causing a computing system to perform functions comprising:
a. performing a wavelet transform on at least one non-stationary signal acquired from a targeted region of a brain of a living subject to compute corresponding wavelet coefficients; and
b. extracting features from the computed coefficients.
